(19) United States
(12) Patent Application Publication
(10) Pub. No.: US 2007/0080441 A1
(43) Pub. Date: Apr. 12, 2007

(54) Thermal expansion compensation graded IC package

(76) Inventors: Scott Kirkman, Menlo Park, CA (US); Bidyut Sen, Milpitas, CA (US)

Correspondence Address: HAMILTON & TERRILE, LLP, P.O. BOX 203518, AUSTIN, TX, 78720, US

(21) Appl. No.: 11/206,568

(22) Filed: Aug. 18, 2005

(51) Int. Cl. H01L 23/02

(52) U.S. Cl. 257/686

(57) ABSTRACT

An apparatus and method for connecting one substrate, such as a semiconductor die, to an opposing substrate, such as a semiconductor package or circuit board, through a plurality of intermediate thermal compensator devices, each of which can incrementally and/or locally mitigate the stresses imposed by differences in the two substrate's thermal expansion characteristics. The compensator devices can be coupled to one another, with the resulting assembly attached to the first substrate on one side, and to the second substrate on the other side, through solder bump attach, or some equivalent method. The method of the invention provides electrical connection and thermal dissipation between the two substrates as well as providing mechanical protection by absorbing the stresses imposed by the difference in thermal expansion characteristics of the two substrates.

### BACKGROUND OF THE INVENTION

1. Field of the Invention

The present invention relates to packaging integrated circuits, and more specifically, to mitigating the stresses imposed when bonding two or more substrates with different thermal expansion characteristics.

2. Description of the Related Art

Integrated circuit technology continues to evolve, resulting in chips with increased clock speeds, higher power consumption, and larger numbers of inputs and outputs. Corresponding advances in integrated circuit fabrication technology have resulted in higher levels of integration, increased density, and growth in die sizes.

A semiconductor device is an integrated circuit in packaged form, usually mounted to printed circuit boards (“circuit boards”) or other type of carrier, operating as a processing unit, memory, controller or any other electronic device. Semiconductor package and packaging techniques are designed to provide electrical connection between the integrated circuit and external electrical devices, thermal dissipation during operation, and most relevant to the present invention, protect the integrated circuit from mechanical and environmental damage.

A fundamental issue in semiconductor package mounting is the thermal expansion differences between the semiconductor device and the circuit board. Mechanical protection of the semiconductor device can be jeopardized if thermal mismatches between the device, package and/or circuit board are not sufficiently accommodated. A great deal of stress can be generated within the combined structure if the device expands and contracts at one rate while the package and/or circuit board moves at vastly different rates. These stresses can produce failures within the components themselves or at any of the interfaces between components.

The flip-chip method of device-to-package attachment is especially sensitive to this issue. Such flip chip and substrate attachments (collectively referred to as “packages”) are generally comprised of dissimilar materials that expand at different rates when heated. The most severe stress is due to the inherently large thermal coefficient of expansion mismatch between the plastics and the metals commonly used in fabrication techniques. These packages are subject to exposures during fabrication process cycles, which are few in number but often high in temperature, and operation cycles, which are numerous but with less extreme temperature variations.

As a package dissipates heat to its surroundings, differential thermal expansions cause stresses to be generated in the interconnection structure between the semiconductor die and the substrate. These stresses produce instantaneous elastic and plastic strains, particularly at the weakest interconnection structure, which causes shear displacements that can fracture solder ball connections. Over its lifetime, the functionality of the electronic package will be destroyed if the flip chip and/or substrate are unable to repeatedly bear their respective share of thermal mismatch.

As the device size grows, the issue can become more pronounced, resulting in the dilemma of whether package thermal expansion should be matched to the device or the circuit board. Both approaches have been employed with varying degrees of success. For example, if the thermal expansion coefficient of the package is matched more closely to the device, then the attachment method between the board and the package should be compliant enough to absorb the associated movement and mitigate the resulting stresses that are generated.

Current solutions that provide a compliant interface with the materials themselves, or sufficient distance (i.e., “stand-off”) between the package and circuit board include sockets, solder columns, pins and interposers. Each of these methods has advantages and drawbacks.

Sockets present significant cost versus performance trade-offs. A socket that represents a marginal material cost increase can result in significant electrical performance degradation. Further, such sockets may require pins to be placed on the package, adding process steps and cost, thereby offsetting potential savings. Conversely, a socket that does not degrade performance or require pins can cost as much as the package itself. In addition, such sockets can require significant force be placed on the package to ensure good socket contact, which limits mechanical and thermal design solutions. Additionally, sockets or interposers can degrade the reliability of the package.

Solder columns are another solution with a different set of trade-offs. They provide proper stand-off and ensure good electrical connection, but they are difficult to process and currently limited in the supplier base. Another solution is the use of solders with different melting, or re-flow, temperatures. Components within this solder attach method can be designed with solders having higher melting points. These solders act as a stand-off to maintain a greater distance between the package and circuit board because they won't melt and collapse during the normal board mount process. However, this method adds complications and associated costs to the assembly process.

Interposers are yet another solution, but currently this solution is relatively untested and inherently undesirable, as they can result in higher material costs, additional processing costs during assembly, and they do not allow interconnection routing.

As discussed, the attachment method between the device and the circuit board should absorb inherent stresses. For example, Controlled Collapse Chip Connection (C4) solder bump technology provides both electrical and mechanical connections. After the C4 solder bump is reflowed, an epoxy encapsulant is underfilled between the die and the substrate. Unfortunately, as the device grows larger, even the underfill cannot reduce inherent stresses to non-fatal levels, and if used alone, could require significant process and material development to become a viable solution for large dies.

Additionally, there are other areas of concern in designing the package-to-die interface for a semiconductor. These can include the actual structures within the die itself, in particular the dielectric layers. To improve die performance, dielectrics with lower and lower K values are being employed. Unfortunately, a dielectric material's strength seems to be directly proportional to its K value, causing the dielectric material to become more susceptible to stress as its K value decreases. Likewise, the interconnections from the die, through the package, and then to the system board, are now being designed as an integrated unit to ensure desired electrical characteristics including high-conductivity interconnect traces, low capacitance, and matched impedance.

Current trends in semiconductor design to aggressively increase circuit density, with a corresponding reduction in die sizes, can result in increased heat dissipation, which in turn can exacerbate coefficient of thermal expansion (CTE) mismatch between package components. Furthermore, when die size shrinks, the number of connections does not. This can result in a decrease in the bump pitch for a flip-chip, which often means increasing the number of connections to support the additional power required for increased performance. The combined effect of reduced bump pitch and increased power connectors further affects CTE mismatch.

The current industry trend of transitioning from ceramic to organic laminate packages addresses some, but not all, of these thermal management challenges. Use of organic packages, comprised of epoxy resin materials exhibiting low dielectric characteristics, and copper interconnects delivering high conductivity, can result in substantial improvements in power distribution and signal transmission. However, while the CTE of organic packaging is more closely matched to that of the circuit board than ceramic, it may be insufficient to accommodate certain CTE mismatch situations.

For example, clustering of high power units can lead to localized concentrations of higher heat flux, manifested as large temperature gradients across the surface of the die, whose variations may be too great to be accommodated by the CTE of an organic package. Similarly, the CTE characteristics of a given organic package may not be able to accommodate the aggregate CTE of individual components comprising a composite semiconductor assembly. Likewise, the total CTE mismatch between a die and a circuit board may be greater than a package can accommodate by itself, regardless of its composition.

Semiconductor packaging technology, by addressing the design space from the silicon to the board level, is now evolving into a sophisticated thermal and electrical management platform, capable of ensuring chip functionality and reliability. What is needed are solutions capable of supporting this evolution without resulting in higher material costs or additional processing costs at time of manufacture.

### SUMMARY OF THE INVENTION

In accordance with the present invention, an approach for incrementally and/or locally mitigating the stresses imposed when bonding two or more substrates with different thermal expansion characteristics is set forth which incrementally and/or locally compensates for the thermal expansion differences between a semiconductor die and package by the insertion of a plurality of intermediate compensator devices between the die, other devices, and the package. The compensator devices can be physically connected on either side to the package, another compensator device, other devices, or the die, as needed through solder bump attach, or some equivalent method. The approach provides electrical connection and thermal dissipation between the die and package as well as providing mechanical protection for the die bumps and internal die structures by absorbing the stresses imposed by the thermal expansion differences.

In one embodiment of the invention, when the die is made from silicon, and the package from a high CTE material (either organic material or ceramic material), an intermediate compensator device can be constructed of alumina ceramic, or similar material with the same general characteristics, formulated to have CTE characteristics close to die. In this same embodiment, another intermediate compensator can be constructed from a material, or combination of materials, such that its thermal expansion properties are closer to the package or circuit board. The die is attached to a first intermediate compensator, which is then attached to a second intermediate compensator, which in turn is attached either to a package or circuit board. Electrical connection is made by passing vias directly through the compensators, from the die bumps to the compensator bumps, and on to the package bumps. This embodiment is useful because stresses are incrementally distributed not just between die bumps and package bumps, but also between die and the package or circuit board. The method of the embodiment is particularly pertinent when the die is very large.

In this embodiment, the stresses on the bumps between the die and the compensator are minimal, which translates to minimal stresses within the die structures, and in particular, the low and ultra low K dielectric layers. Higher reliability can be achieved if the stresses imposed on these areas can be transferred to a more resilient interface. Consequently, the stresses imposed by the thermal expansion differences are concentrated on the bumps between the compensator and the package. These resulting stresses can be mitigated through the use of intermediate compensator devices, sizing the package bumps properly, and insuring good underfill processes.

In another embodiment of the invention, the compensator is used as a thermal expansion absorption device and also as an electrical performance enhancement. High capacitance materials or capacitive structures can be built into the compensator to allow charge to be stored very close to the die, which is very advantageous for high frequency power distribution. Variations on this embodiment include the use of a plurality of intermediate compensators, each with their associated capacitive structures or fine detail interconnections and vias.

In another embodiment of the invention, the compensator can be expanded in size to allow for discrete capacitors to be placed on its surface. In this embodiment, metal planes can be added to the compensator to provide proper electrical connection between the die and the discrete capacitors. Variations on this embodiment include the use of a plurality of intermediate compensators, each with their associated discrete capacitors or fine detail interconnections and vias.

In another embodiment of the invention, the intermediate compensators can be used to redistribute the die bump array to a larger array on the package. Die process technology generally shrinks its feature sizes faster than corresponding packaging technologies. In this embodiment, the compensator can enable greater die shrinks without a corresponding reduction in package size. Similarly, the method of the embodiment provides an expansion of packaging technology options. In both cases, positive impacts on overall product costs can be realized.

In another embodiment of the invention, the intermediate compensators can be constructed from a material, or combination of materials, such that the thermal expansion properties of each compensator fall close to the die, other devices, other intermediate compensators, the package or circuit board. This embodiment is useful because stresses are more evenly distributed between the die bumps, other device bumps, intermediate compensator bumps, package bumps, and board bumps. The method of the embodiment is particularly pertinent when the die is very large but dielectric layers within the die are not made from low or ultralow K materials.

In another embodiment of the invention, each compensator's thermal expansion characteristics can be tuned by placing holes in the structure, thereby removing material. This method of the embodiment is useful when the compensator's thermal expansion characteristics need to accommodate the stresses induced by a predetermined configuration of die, other devices, intermediate compensators, package, and circuit board. For example, a circuit board can be constructed of a resin-based material and the die from silicon, coupled by a plurality of intermediate compensators. In this example, the package could be manufactured from organic material, or high CTE glass ceramic. Each compensator could then be made from a high temperature co-fired ceramic, such as alumina, or a low CTE ceramic. Each compensator's specific thermal expansion characteristics are then adjusted by removing an appropriate amount of material to reduce the thermally-induced stress placed on each adjacent component of the combination. This example describes one combination of die, compensators, package, and circuit board. Many such combinations are possible.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a computer system in accordance with an embodiment of the present invention.

FIG. 2 shows an embodiment of the present invention providing electrical connection between a semiconductor die and package, as well as mechanical protection for the die bumps and internal die structures, by absorbing the stresses imposed by differences in each component's thermal expansion characteristics.

FIG. 3 shows an embodiment of the present invention where electrical connection is made by passing vias directly through the compensator from the die bumps to the package bumps.

FIG. 4 shows an embodiment of the present invention that provides electrical performance enhancement by allowing capacitive structures to be built into the compensator.

FIG. 5 shows an embodiment of the present invention where the compensator can be expanded in size to allow for discrete capacitors to be placed on its surface.

FIG. 6 is a shows an embodiment of the present invention where a plurality of intermediate compensators are utilized for incremental mitigation of thermal stresses.

FIG. 7 shows an embodiment of the present invention where a plurality of intermediate compensators are utilized for incremental mitigation of thermal stresses, with one compensator expanded in size to allow for discrete capacitors to be placed on its surface.

FIG. 8 shows an embodiment of the present invention where a plurality of intermediate compensators are utilized for incremental mitigation of thermal stresses within a plurality of composite structures sharing a common package.

### DETAILED DESCRIPTION

Although the present invention has been described in detail, it should be understood that various changes, substitutions and alterations can be made hereto without departing from the spirit and scope of the invention as defined by the appended claims.

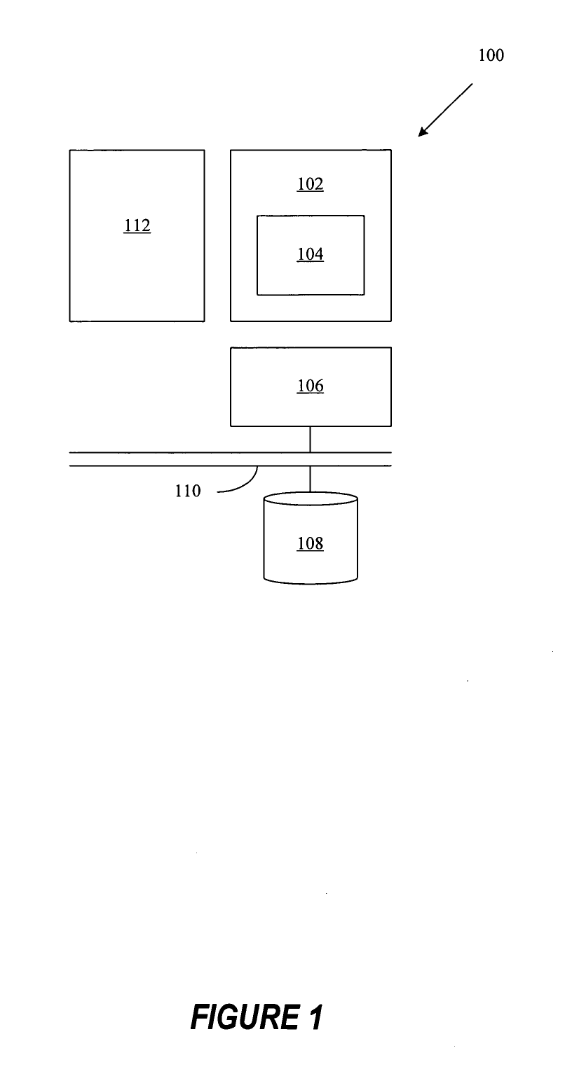

FIG. 1 shows a computer system 100 in accordance with an embodiment of the present invention. As illustrated in FIG. 1, computer system 100 includes processor 102, which is coupled to a memory 112 and to peripheral bus 110 through bridge 106. Bridge 106 can generally include any type of circuitry for coupling components of computer system 100 together.

Processor 102 can include any type of processor, including, but not limited to, a microprocessor, a mainframe computer, a digital signal processor, a personal organizer, a device controller and a computational engine within an appliance. Processor 102 includes a cache 104 that stores code and data for execution by processor 102.

Processor 102 communicates with storage device 108 through bridge 106 and peripheral bus 110. Storage device 108 can include any type of non-volatile storage device that can be coupled to a computer system. This includes, but is not limited to, magnetic, optical, and magneto-optical storage devices, as well as storage devices based on flash memory and/or battery-backed up memory.

Processor 102 communicates with memory 112 through bridge 106. Memory 112 can include any type of memory that can store code and data for execution by processor 102.

For purposes of this disclosure, the present invention is described in the context of computer system 100 illustrated in FIG. 1. However, the present invention can generally operate on any type of electronic device, including any instrumentality or aggregate of instrumentalities operable to compute, classify, process, transmit, receive, retrieve, originate, store, display, manifest, detect, record, reproduce, handle, or utilize any form of information, intelligence or data for business, scientific, control or other purposes. For example, such a system may be a personal computer, a network storage device, or any other suitable device and may vary in size, shape performance, functionality, and price. The referenced system may include random access memory (RAM), one or more processing resources such as a central processing unit (CPU) or hardware or software control logic, read only memory (ROM), and/or other types of nonvolatile memory. Additional components of the referenced system may include one or more disk drives, one or more network ports for communicating with external devices as well as various input and output (I/O) devices, such as a keyboard, a mouse, and a video display. The referenced system may also include one or more buses operable to transmit communications between the various hardware components. Hence, the present invention is not limited to the specific computer system 100 illustrated in FIG. 1.

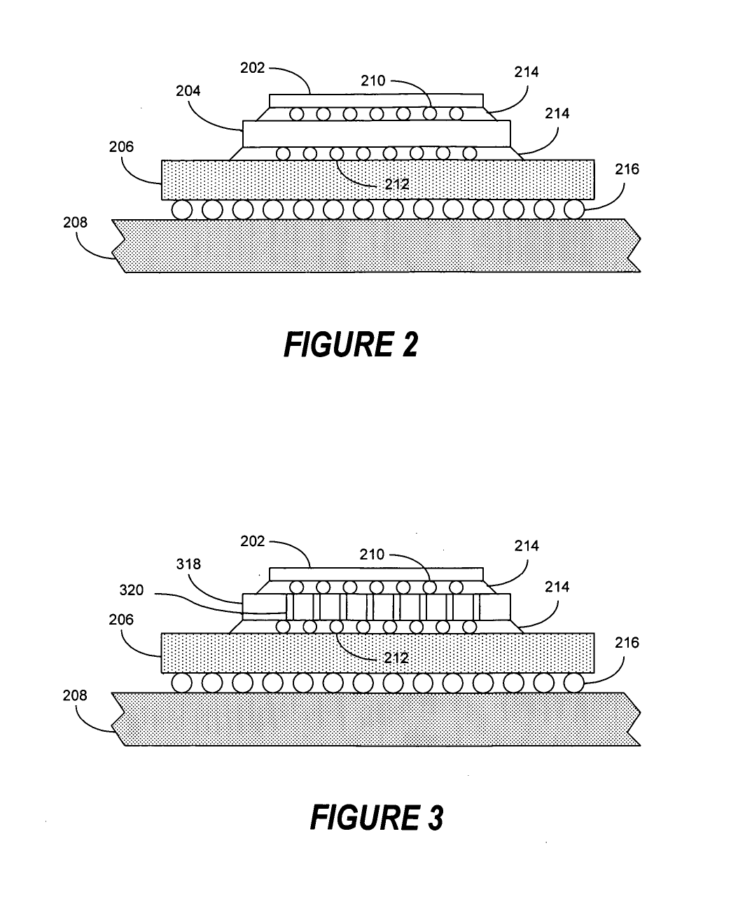

FIG. 2 is a generalized illustration of an approach for mitigating the stresses imposed when bonding two or more substrates with different thermal expansion characteristics. More specifically, the approach which compensates for the thermal expansion differences between a semiconductor die 202 and package 206 by the insertion of a compensator device 204 between die 202 and package 206. The compensator device 204 can be physically connected through solder package bump 212 attach, or some equivalent method, to package 206 on one side, and to die 202 on the other side, through solder die bump 210 attach, or some equivalent method.

The compensator 204, when connected as described hereinabove, between a semiconductor die 202 and package 206, can provide electrical and mechanical connection, thermal dissipation during operation and assembly processing, and mechanical protection for die bumps 210 and internal structures of die 202 by absorbing the stresses imposed by differences in each component's thermal expansion characteristics.

After assembling the die 202, compensator 204, and package 206 with die solder bump 210 and package bump 212 attach, or some equivalent method, a non-conductive underfill 214 adhesive is injected to join the individual components into a single assembly. The resulting assembly can then be mounted to a circuit board 208, or other substrate, through the use of solder ball 216 attach, or some equivalent method.

FIG. 3 is a generalized illustration of another approach for mitigating the stresses imposed when bonding two or more substrates with different thermal expansion characteristics. In this approach, when die 202 is made from silicon, and the package 206 from an organic material, compensator 318 can be constructed of alumina ceramic, or similar material with the same general characteristics. Electrical connection is made by passing vias 320 directly through compensator 318, from die bumps 210 to package bumps 212. The thermal expansion properties of alumina are between that of die 202 and package 206, but much closer to die 202.

In this approach, the stresses on die bumps 210 between die 202 and compensator 318 are minimal, which translates to minimal stresses within die structures, and in particular, low and ultra low K dielectric layers. Higher reliability can be achieved if the stresses imposed on these areas can be transferred to a more resilient interface. Consequently, the stresses imposed by the thermal expansion differences are concentrated on package bumps 212 between compensator 318 and package 206. These resulting stresses can be mitigated by sizing package bumps 212 properly and insuring good underfill 214 processes.

After assembling the die 202, compensator 318, and package 206 with die solder bump 210 and package solder bump 212 attach, or some equivalent method, a non-conductive underfill 214 adhesive is injected to join the individual components into a single assembly. The resulting assembly can then be mounted to a circuit board 208, or other substrate, through the use of solder ball 216 attach, or some equivalent method.

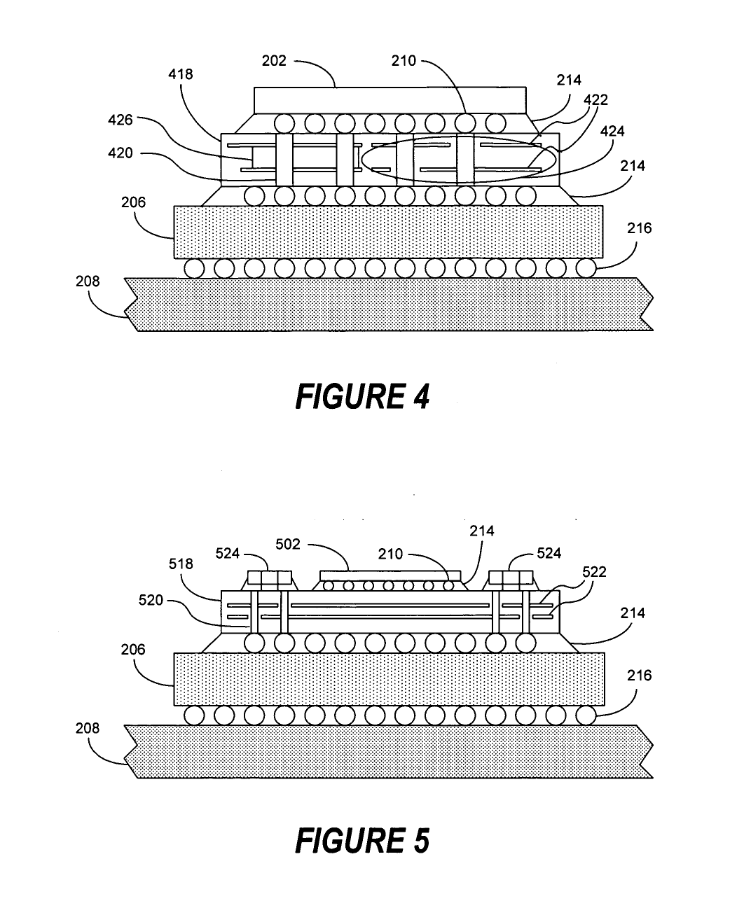

FIG. 4 is a generalized illustration of another approach for mitigating the stresses imposed when bonding two or more substrates with different thermal expansion characteristics. In this approach, compensator 418 is not only used as a thermal expansion absorption device, but as an electrical performance enhancement by building capacitive structures 424, or high capacitance materials 426, into compensator 418.

These capacitive structures 424 and/or high capacitive materials 426 are interconnected with metal planes 422, which in turn make electrical connection to vias 420. The vias 420 provide interconnection from package bumps 212, directly through compensator 418, to die bumps 210, allowing electrical charges to be stored very close to the die 202, which is very advantageous for high frequency power distribution.

After assembling die 202, compensator 418, and package 206 with die solder bump 210 and package solder bump 212 attach, or some equivalent method, a non-conductive underfill 214 adhesive is injected to join the individual components into a single assembly. The resulting assembly, including the capacitive structures 424 and/or high capacitive materials 426 built into compensator 418, can then be mounted to a circuit board 208, or other substrate, through the use of solder ball 216 attach, or some equivalent method.

FIG. 5 is a generalized illustration of another approach for mitigating the stresses imposed when bonding two or more substrates with different thermal expansion characteristics. In this approach compensator 518 is not only used as a thermal expansion absorption device, but as an electrical performance enhancement by expanding the size of the compensator 518 to allow for discrete capacitors 524 to be placed on its surface.

These discrete capacitors 524 are interconnected with metal planes 522, built into the compensator 518, which in turn make electrical connection to vias 520. The vias 520 provide interconnection from package bumps 212, directly through compensator 518, to die bumps 210, allowing electrical charges to be stored very close to the die 502, which is very advantageous for high frequency power distribution.

After assembling die 502, compensator 518, and package 206 with die solder bump 210 and package solder bump 212 attach, or some equivalent method, a non-conductive underfill 214 adhesive is injected to join the individual components into a single assembly. The resulting assembly, including discrete capacitors 524, can then be mounted to a circuit board 208, or other substrate, through the use of solder ball 216 attach, or some equivalent method.

In another embodiment of the invention, compensator 518 can be used to redistribute a die bump 210 array to a larger package bump 212 array. Die process technology generally shrinks its feature sizes faster than corresponding packaging technologies. In this embodiment, compensator 518 can enable greater die shrinks without a corresponding reduction in package 206 size. Similarly, the method of the embodiment provides an expansion of packaging technology options.

In another embodiment of the invention, compensator 518 can be constructed from a material, or combination of materials, such that its thermal expansion properties fall closer to the midpoint between die 502 and package 206, or circuit board 208. This embodiment is useful because stresses are more evenly distributed between die bumps 210 and package bumps 212. The method of the embodiment is particularly pertinent when the die 502 is very large but dielectric layers within the die 502 are not made from low or ultralow K materials.

In another embodiment of the invention, thermal expansion characteristics of the compensator 518 can be tuned by placing holes in the structure, thereby removing material. This method of the embodiment is useful when the thermal expansion characteristics of the compensator 518 need to accommodate the stresses induced by a predetermined configuration of die 502, package 206, and circuit board 208.

For example, a circuit board 208 can be constructed of a resin-based material and the die 502 from silicon. In this example, the package 206 could be manufactured from organic material, or high CTE (Coefficient of Thermal Expansion) glass ceramic. The compensator 518 could then be made from a high temperature co-fired ceramic, such as alumina, or a low CTE ceramic. The specific thermal expansion characteristics of the compensator 518 are then adjusted by removing an appropriate amount of material to reduce the thermally-induced stress placed on each component of the combination. This example describes one combination of die 502, package 206, circuit board 208, and compensator 518. Those skilled in the art will recognize that many such combinations are possible.

In another embodiment of the invention, the compensator may provide electrical performance enhancement by expanding the size of the compensator so all voltage regulators or voltage regulator modules may be placed on the surface of the compensator.

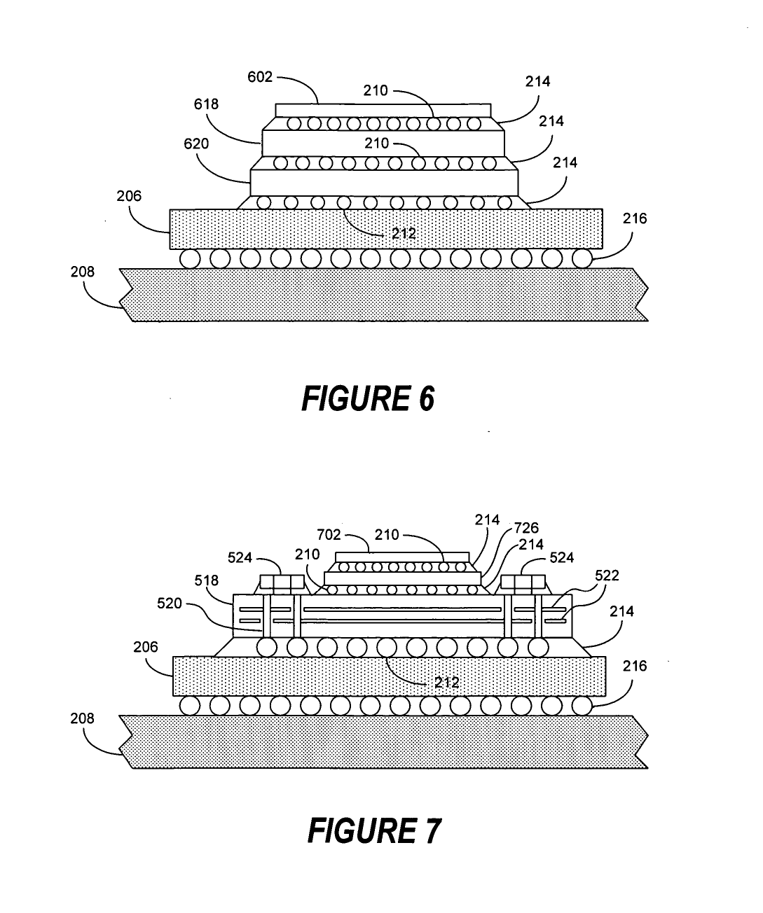

FIG. 6 is a generalized illustration of an approach for incremental mitigation of the stresses imposed when bonding two or more substrates whose CTE differential may not be satisfactorily mitigated by a single compensator device. More specifically, the approach compensates for the thermal expansion differences between a semiconductor die 602 and package 206 by the insertion of a plurality of compensator devices 618, 620, each with differing CTE characteristics, between die 602 and package 206.

In this approach, when die 602 is made from silicon, and the package 206 from an organic material, compensator device 618 can be constructed of alumina ceramic, or similar material with the same general characteristics, formulated to have CTE characteristics close to die 602. In this same approach, compensator 620 can be constructed from a material, or combination of materials, such that its thermal expansion properties are closer to the package 206, or circuit board 208. This embodiment is useful because stresses are incrementally distributed not just between die bumps 210 and package bumps 212, but also between die 602 and the package 206, or circuit board 208. The method of the embodiment is particularly pertinent when the die 602, or package 206, is very large.

In this approach, compensator device 620 can be physically connected through solder package bump 212 attach, or some equivalent method, to package 206 on one side, and to one side of compensator 618 on the other side, through solder die bump 210 attach, or some equivalent method. The other side of compensator 618, can then be physically connected to die 602 on the other side, through solder die bump 210 attach, or some equivalent method.

Compensator devices 618 and 620, when connected as described hereinabove, between a semiconductor die 602 and package 206, can provide electrical and mechanical connection, thermal dissipation during operation and assembly processing, and mechanical protection for die bumps 210 and internal structures of die 602 by absorbing the stresses imposed by differences in each component's thermal expansion characteristics.

After assembling the die 602, compensator devices 618 and 620, and package 206 with die solder bump 210 and package bump 212 attach, or some equivalent method, a non-conductive underfill 214 adhesive is injected to join the individual components into a single assembly. The resulting assembly can then be mounted to a circuit board 208, or other substrate, through the use of solder ball 216 attach, or some equivalent method.

In another embodiment of the invention, a plurality of intermediate compensators 618, 620, can be used to redistribute a die bump 210 array to a larger package bump 212 array. Die process technology generally shrinks its feature sizes faster than corresponding packaging technologies. In this embodiment, intermediate compensators 618, 620, can enable greater die shrinks without a corresponding reduction in package 206 size. Similarly, the method of the embodiment provides an expansion of packaging technology options.

FIG. 7 is a generalized illustration of another approach for incremental mitigation of the stresses imposed when bonding two or more substrates whose CTE differential may not be satisfactorily mitigated by a single compensator device.

More specifically, the approach compensates for the thermal expansion differences between a semiconductor die 702 and package 206 by the insertion of a plurality of compensator devices 518, 726, each with differing CTE characteristics, between die 602 and package 206.

In this approach compensator 518 is not only used as a thermal expansion absorption device, but as an electrical performance enhancement by expanding the size of the compensator 518 to allow for discrete capacitors 524 to be placed on its surface.

In this same approach, when die 702 is made from silicon, and the package 206 from an organic material, compensator device 726 can be constructed of alumina ceramic, or similar material with the same general characteristics, formulated to have CTE characteristics close to die 702. In this same approach, compensator 518 can be constructed from a material, or combination of materials, such that its thermal expansion properties are closer to the package 206, or circuit board 208.

This approach is useful because stresses are more evenly distributed between die bumps 210 and package bumps 212, particularly if the package 206 is large. The method of the embodiment is particularly pertinent when the die 702 is very large but dielectric layers within the die 702 are not made from low or ultralow K materials.

In this same approach, compensator device 518 can be physically connected through solder package bump 212 attach, or some equivalent method, to package 206 on one side, and to one side of compensator 726 on the other side, through solder die bump 210 attach, or some equivalent method. The other side of compensator 726, can then be physically connected to die 702 on the other side, through solder die bump 210 attach, or some equivalent method.

In this same approach compensator 518 is not only used as a thermal expansion absorption device, but as an electrical performance enhancement by expanding the size of the compensator 518 to allow for discrete capacitors 524 to be placed on its surface.

These discrete capacitors 524 are interconnected with metal planes 522, built into the compensator 518, which in turn make electrical connection to vias 520. The vias 520 provide interconnection from package bumps 212, directly through compensator 518, to die bumps 210, allowing electrical charges to be stored very close to the die 702, which is very advantageous for high frequency power distribution.

After assembling die 702, compensator 726, compensator 518, and package 206 with die solder bump 210 and package solder bump 212 attach, or some equivalent method, a non-conductive underfill 214 adhesive is injected to join the individual components into a single assembly. The resulting assembly, including discrete capacitors 524, can then be mounted to a circuit board 208, or other substrate, through the use of solder ball 216 attach, or some equivalent method.

After assembling the die 702, compensator devices 726 and 518, and package 206 with die solder bump 210 and package bump 212 attach, or some equivalent method, a non-conductive underfill 214 adhesive is injected to join the individual components into a single assembly. The resulting assembly can then be mounted to a circuit board 208, or other substrate, through the use of solder ball 216 attach, or some equivalent method.

Compensator devices 726 and 518, when connected as described hereinabove, between a semiconductor die 702 and package 206, can provide electrical and mechanical connection, thermal dissipation during operation and assembly processing, and mechanical protection for die bumps 210 and internal structures of die 202 by absorbing the stresses imposed by differences in each component's thermal expansion characteristics.

In another embodiment of the invention, thermal expansion characteristics of the compensator 518 can be tuned by placing holes in the structure, thereby removing material. This method of the embodiment is useful when the thermal expansion characteristics of the compensator 518 need to accommodate the stresses induced by a predetermined configuration of die 702, compensator 518, compensator 726, package 206, and circuit board 208.

In another embodiment of the invention, a plurality of intermediate compensators 518, 726, can be used to redistribute a die bump 210 array to a larger package bump 212 array. Die process technology generally shrinks its feature sizes faster than corresponding packaging technologies. In this embodiment, intermediate compensators 518, 726, can enable greater die shrinks without a corresponding reduction in package 206 size. Similarly, the method of the embodiment provides an expansion of packaging technology options.

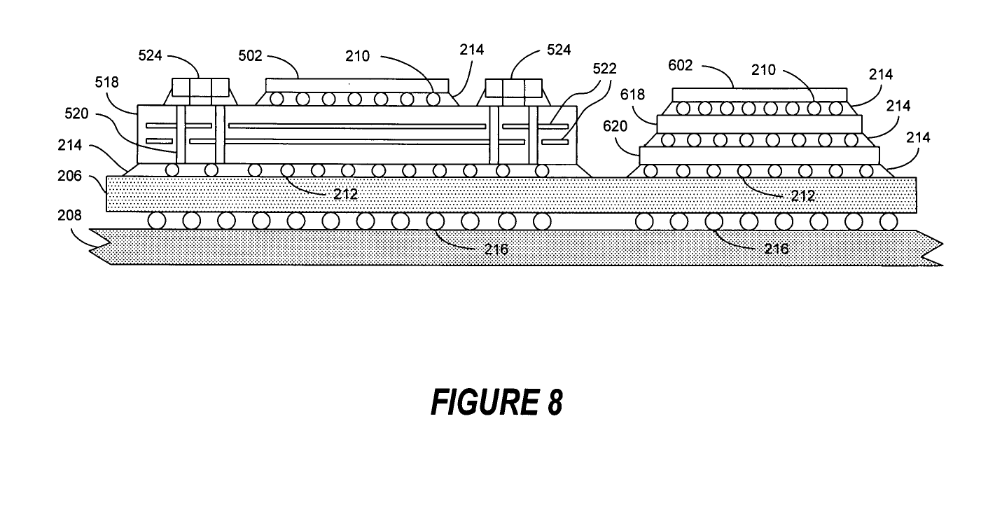

FIG. 8 is a generalized illustration of another approach for incremental mitigation of the stresses imposed when bonding two or more substrates whose CTE differential may not be satisfactorily mitigated by a single compensator device.

More specifically, the approach compensates for the thermal expansion differences between a plurality of semiconductor die 502, 602, and a single package 206 by the insertion of a plurality of compensator devices 518, 618, 620, each with differing CTE characteristics, respectively between die 502, 602 and package 206.

In this approach compensator 518 is not only used as a thermal expansion absorption device, but as an electrical performance enhancement by expanding the size of the compensator 518 to allow for discrete capacitors 524 to be placed on its surface.

These discrete capacitors 524 are interconnected with metal planes 522, built into the compensator 518, which in turn make electrical connection to vias 520. The vias 520 provide interconnection from package bumps 212, directly through compensator 518, to die bumps 210, allowing electrical charges to be stored very close to the die 502, which is very advantageous for high frequency power distribution.

This approach is useful because stresses are more evenly distributed between die bumps 210 and package bumps 212, particularly if the package 206 is large. The method of the embodiment is particularly pertinent when the die 502 is very large but dielectric layers within the die 502 are not made from low or ultralow K materials.

In this same approach, when die 602 is made from silicon, and the package 206 from an organic material, compensator device 618 can be constructed of alumina ceramic, or similar material with the same general characteristics, formulated to have CTE characteristics close to die 602. In this same approach, compensator 620 can be constructed from a material, or combination of materials, such that its thermal expansion properties are closer to the package 206, or circuit board 208. This embodiment is useful because stresses are incrementally distributed not just between die bumps 210 and package bumps 212, but also between die 602 and the package 206, or circuit board 208. The method of the embodiment is particularly pertinent when either the die 602, or the package 206, is very large.

In this same approach, compensator device 620 can be physically connected through solder package bump 212 attach, or some equivalent method, to package 206 on one side, and to one side of compensator 618 on the other side, through solder die bump 210 attach, or some equivalent method. The other side of compensator 618, can then be physically connected to die 602 on the other side, through solder die bump 210 attach, or some equivalent method.

After assembling die 502, compensator 518, and package 206 with die solder bump 210 and package solder bump 212 attach, or some equivalent method, a non-conductive underfill 214 adhesive is injected to join the individual components into a single assembly. The resulting assembly, including die 502, die 602, and discrete capacitors 524, can then be mounted to a circuit board 208, or other substrate, through the use of solder ball 216 attach, or some equivalent method.

Compensator devices 518, 618, and 620, when respectively connected as described hereinabove, between a semiconductor die 702 and package 206, can provide electrical and mechanical connection, thermal dissipation during operation and assembly processing, and mechanical protection for die bumps 210 and internal structures of die 202 by absorbing the stresses imposed by differences in each component's thermal expansion characteristics.

In another embodiment of the invention, thermal expansion characteristics of the compensator 518 can be tuned by placing holes in the structure, thereby removing material. This method of the embodiment is useful when the thermal expansion characteristics of the compensator 518 need to accommodate the stresses induced by a predetermined configuration of die 502 and compensator 518, in combination with a predetermined configuration of die 602, compensator 618, and compensator 620, when both predetermined configurations are mounted on a common package 206, and circuit board 208.

For example, a circuit board 208 can be constructed of a resin-based material and the die 502, 602 from silicon. In this example, the package 206 could be manufactured from organic material, or high CTE (Coefficient of Thermal Expansion) glass ceramic. The compensator 518 could then be made from a high temperature co-fired ceramic, such as alumina, or a low CTE ceramic. The specific thermal expansion characteristics of the compensator 518 are then adjusted by removing an appropriate amount of material to not just reduce the thermally-induced stress placed on each component of the combination, but to match the aggregated CTE characteristics of the assembly comprised of die 602, compensator 618, and compensator 620. This example describes one combination of die 502, compensator 518, die 602, compensator 618, compensator 620, package 206, and circuit board 208. Those skilled in the art will recognize that many such combinations are possible.

In another embodiment of the invention, a plurality of intermediate compensators 518, 618, 620, can be used to redistribute a die bump 210 array to a larger package bump 212 array. Die process technology generally shrinks its feature sizes faster than corresponding packaging technologies. In this embodiment, intermediate compensators 518, 618, 620, can enable greater die shrinks without a corresponding reduction in package 206 size. Similarly, the method of the embodiment provides an expansion of packaging technology options.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Use of the present invention will provide, at a minimum, electrical connection and thermal dissipation between a semiconductor die and package, as well as mechanical protection for the die bumps and internal die structures by absorbing the stresses imposed by the differences in each component's thermal expansion characteristics. Further, vias and metal planes built into the invention can provide electrical connectivity between the die and the package, as well as to capacitive material and structures within the compensator and discrete capacitors mounted on the package itself. In addition, the invention allows the redistribution of die bump arrays to larger package arrays, accommodating advances in die size reductions in absence of a corresponding reduction in package size. In all cases, higher reliability and positive impacts on overall product costs can be realized.

Consequently, the invention is intended to be limited only by the spirit and scope of the appended claims, giving full cognizance to equivalents in all respects.

What is claimed is:

1. An apparatus for mitigating the stresses imposed when bonding two or more substrates with different thermal expansion characteristics comprising:
a first die having first thermal expansion characteristics;
a package having second thermal expansion characteristics; and,
a first compensator thermally coupled to the first die, the first compensator absorbing stresses imposed by thermal expansion differences between the first thermal expansion characteristics and intermediate thermal expansion characteristics;
a second compensator thermally coupled between the first compensator and the package, the second compensator absorbing stresses imposed by thermal expansion differences between the intermediate thermal expansion characteristics and the second thermal expansion characteristics.

2. The apparatus of claim 1 wherein:
the first compensator is constructed of alumina ceramic.

3. The apparatus of claim 1 wherein:
the first compensator includes vias, the vias passing electrical connections between the first die and the package;
the second compensator includes vias, the via passing electrical connections between the second die and the package.

4. The apparatus of claim 3 further comprising:
the first and second compensators each include signal layers, certain vias being coupled to certain signal layers to redistribute electrical signals within the compensator.

5. The apparatus of claim 1 wherein:
package bumps are interposed between the compensator and a package.

6. The apparatus of claim 1 wherein:
die bumps are interposed between the first die and the first compensator.

7. The apparatus of claim 1 wherein:
the first and second compensators each include a capacitive structure, the capacitive structure allowing charge to be stored between the package and the die.

8. An apparatus for mitigating the stresses imposed when bonding two or more substrates with different thermal expansion characteristics comprising:
a first die having first thermal expansion characteristics;
a second die having second thermal expansion characteristics;
a package having third thermal expansion characteristics; and,
a first compensator thermally coupled between the first die and the package, the first compensator absorbing stresses imposed by thermal expansion differences between the first thermal expansion characteristics and the third thermal expansion characteristics;
a second compensator thermally coupled between the second die and the package, the second compensator absorbing stresses imposed by thermal expansion differences between the second thermal expansion characteristics and the third thermal expansion characteristics.

9. The apparatus of claim 8 wherein:
the first compensator is constructed of alumina ceramic.

10. The apparatus of claim 8 wherein:
the first compensator includes vias, the vias passing electrical connections between the first die and the package;
the second compensator includes vias, the via passing electrical connections between the second die and the package.

11. The apparatus of claim 10 further comprising:
the first and second compensators each include signal layers, certain vias being coupled to certain signal layers to redistribute electrical signals within the compensator.

12. The apparatus of claim 8 wherein:
package bumps are interposed between the compensator and a package.

13. The apparatus of claim 8 wherein:
die bumps are interposed between the first die and the first compensator.

14. The apparatus of claim 8 wherein:
the first and second compensators each include a capacitive structure, the capacitive structure allowing charge to be stored between the package and the die.

15. A semiconductor device comprising:
a first die having first thermal expansion characteristics;
a package having second thermal expansion characteristics; and,
a first compensator thermally coupled to the first die, the first compensator absorbing stresses imposed by thermal expansion differences between the first thermal expansion characteristics and intermediate thermal expansion characteristics;
a second compensator thermally coupled between the first compensator and the package, the second compensator absorbing stresses imposed by thermal expansion differences between the intermediate thermal expansion characteristics and the second thermal expansion characteristics.

16. The semiconductor device of claim 15 wherein: the first compensator is constructed of alumina ceramic.

17. The semiconductor device of claim 15 wherein:
the first compensator includes vias, the vias passing electrical connections between the first die and the package;
the second compensator includes vias, the via passing electrical connections between the second die and the package.

18. The semiconductor device of claim 17 further comprising:
the first and second compensators each include signal layers, certain vias being coupled to certain signal layers to redistribute electrical signals within the compensator.

19. The semiconductor device of claim 15 wherein:
package bumps are interposed between the compensator and a package.

20. The semiconductor device of claim 15 wherein:
die bumps are interposed between the first die and the first compensator.

21. The semiconductor device of claim 15 wherein:
the first and second compensators each include a capacitive structure, the capacitive structure allowing charge to be stored between the package and the die.
